(19) United States
(12) Patent Application Publication
(10) Pub. No.: US 2015/0325531 A1
(43) Pub. Date: Nov. 12, 2015

(54) THROUGH CRACK STOP VIA

(71) Applicant: INTERNATIONAL BUSINESS MACHINES CORPORATION, Armonk, NY (US)

(72) Inventors: Thomas W. Dyer, Pleasant Valley, NY (US); Bradley P. Jones, Pleasant Valley, NY (US)

(73) Assignee: INTERNATIONAL BUSINESS MACHINES CORPORATION, Armonk, NY (US)

(21) Appl. No.: 14/273,658

(22) Filed: May 9, 2014

(51) Int. Cl. H01L 23/00; H01L 23/50; H01L 23/528; H01L 23/48

(52) U.S. Cl. CPC H01L 23/562; H01L 23/481; H01L 23/50; H01L 23/528

(57) ABSTRACT

A semiconductor device includes an active inner region and a crack stop region. The active inner region includes a semiconductor substrate, an integrated circuit (IC) device layer formed upon the semiconductor substrate, and a wiring layer formed upon the IC device layer. The IC device layer includes an integrated circuit device and the wiring layer includes wiring in electrical contact with the integrated circuit device. The crack stop region limits the propagation of cracks and delamination into the active inner region and includes semiconductor material surrounding a crack stop via (CSV) extending through the crack stop region. A lower surface of the CSV may be coplanar with lower surfaces of the crack stop layer and the active inner layer. An upper surface of the CSV may be coplanar with upper surfaces of the crack stop layer and the active inner layer.

### FIELD

Embodiments of invention generally relate to semiconductor devices, design structures for designing a semiconductor device, and semiconductor device fabrication methods. More particularly, embodiments relate to semiconductor devices with a through silicon crack stop via.

### BACKGROUND

Numerous integrated circuits are typically manufactured on a single semiconductor wafer. The semiconductor wafer comprises semiconductor chips whereupon the integrated circuits are located, and kerfs or scribe lines which separate the chips. The individual chips are diced by sawing the wafer along the kerf. The individual chips are then typically packaged, either separately or in a multi-chip module.

During chip dicing operations, cracks form that can propagate into active areas of the IC chip, causing fails. Therefore, crack stop layers have been incorporated into the perimeter of the chips to prevent cracks formed during chip dicing from propagating into the chip. Cracks generally propagate through the BEOL (back end of line) dielectrics which are generally brittle materials such as silicon oxide.

### SUMMARY

In an embodiment of the present invention, a semiconductor device includes an active inner region and a crack stop region. The active inner region includes a semiconductor substrate, an integrated circuit (IC) device layer formed upon the semiconductor substrate, and a wiring layer formed upon the IC device layer. The IC device layer includes an integrated circuit device and the wiring layer includes wiring in electrical contact with the integrated circuit device. The crack stop region limits the propagation of cracks and delamination into the active inner region and includes semiconductor material surrounding a crack stop via (CSV) extending through the crack stop region.

In another embodiment of the present invention, a wafer includes a plurality of chips, a kerf that separates the plurality of chips, and a crack stop region that separates each chip from the kerf. Each chip includes an active inner region that includes a semiconductor substrate, an integrated circuit (IC) device layer formed upon the semiconductor substrate, and a wiring layer formed upon the IC device layer. The IC device layer including an integrated circuit device and the wiring layer including wiring in electrical contact with the integrated circuit device. The crack stop region includes semiconductor material surrounding a crack stop via (CSV) extending through the crack stop region.

In another embodiment, a design structure tangibly embodied in a machine readable storage medium for designing, manufacturing, or testing a semiconductor device, includes at least the active inner region and the crack stop region.

These and other embodiments, features, aspects, and advantages will become better understood with reference to the following description, appended claims, and accompanying drawings.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a wafer, in accordance with various embodiments of the present invention.

FIG. 2 depicts multiple chips diced from the wafer, in accordance with various embodiments of the present invention.

FIG. 3-FIG. 7 depict cross section views of a semiconductor structure at intermediate stages of semiconductor device fabrication, in accordance with various embodiments of the present invention.

FIG. 8-FIG. 11 depict top views of a semiconductor structure at intermediate stages of semiconductor device fabrication, in accordance with various embodiments, of the present invention.

FIG. 12-FIG. 13 depict exemplary semiconductor device fabrication process flow methods, in accordance with various embodiments of the present invention.

FIG. 14-FIG. 17 depict top views of semiconductor structures at intermediate stages of semiconductor device fabrication, in accordance with various embodiments of the present invention.

FIG. 18 depicts a flow diagram of a design process used in semiconductor design, manufacture, and/or test, in accordance with various embodiments of the present invention.

The drawings are not necessarily to scale. The drawings are merely schematic representations, not intended to portray specific parameters of the invention. The drawings are intended to depict only exemplary embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. These exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

Embodiments of invention generally relate to semiconductor devices, such as a semiconductor chip (chip). The chip may be planar device and may comprise planar electrodes in parallel planes, made by alternate diffusion of p- and n-type impurities into the semiconductor substrate of the chip. Alternatively, the chip may be a FinFET type device and may comprise a plurality of fins formed from or upon the semiconductor substrate and a gate covering a portion of the fins. The portion of the fins covered by the gate may serve as a channel region of the device. Portions of the fins may also extend out from under the gate and may serve as source and drain regions of the device.

Referring now to the FIGs, wherein like components are labeled with like numerals, exemplary fabrication steps of forming a chip 10 in accordance with embodiments of the present invention are shown, and will now be described in greater detail below. It should be noted that some of the FIGs depict various cross section views of a portion of chip 10. Furthermore, it should be noted that while this description may refer to components of the chip 10 in the singular tense, more than one component may be depicted throughout the figures and within the chip 10. The specific number of components depicted in the figures and the cross section orientation was chosen to best illustrate the various embodiments described herein.

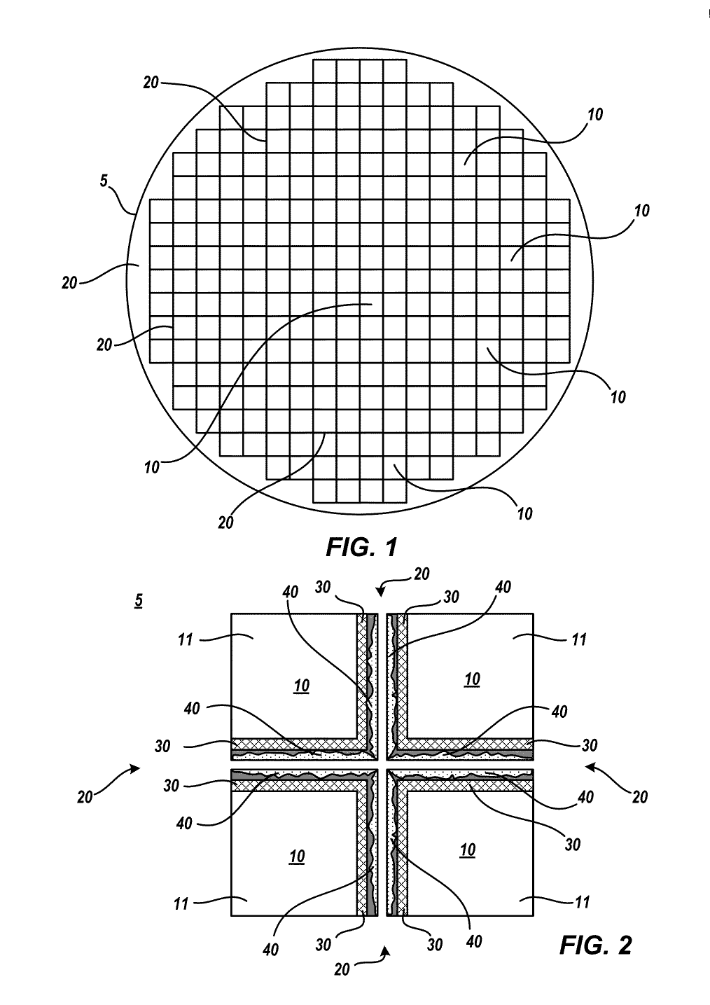

FIG. 1 depicts a wafer 5 comprising a plurality of chips 10 and a plurality of kerfs 20. Each chip 10 may be separated from other chips 10 by kerfs 20. The kerfs 20 may comprise features such e-fuses, alignment structures, fabrication quality/reliability structures, etc.

FIG. 2 depicts multiple chips 10 diced from the wafer 5. Each chip 10 may comprise an inner active region 11 wherein integrated circuits may be formed and a crack stop region 10 separating the active region 11 from kerf 20. Each inner active region 11 may be enclosed or surrounded by the crack stop region 30 located on the periphery of each chip 10. The crack stop region 30 may consist of similar layers or materials as those in active region 10 (e.g. silicon, etc.) and prevents cracks or delamination (C/D) 40 from propagating toward the inner active region 11 of the chips 10 while chips 10 are being diced by sawing the kerf 20. FIG. 2 shows the propagation of C/D 40 while the chips 10 are diced from wafer 5. As can be seen from FIG. 2, the crack stop regions 30 may prevent the propagation of the C/D 40 toward the inner active region 11. If C/D 40 propagate to the inner active regions 11 the chips 10 the integrated circuits within the inner active regions 11 may become damaged leading to semiconductor device failures. The cracks can disrupt conductive lines rendering the integrated circuits 214-217 inoperable. The cracks can also allow moisture and other contaminants to enter into the inner active region 11 of the chips 10, causing corrosion and other problems. Though C/D 40 generally propagate through the BEOL dielectrics, crack stop region 30 offers increased robust crack prevention structures to limit the C/D 40 propagation into active regions 11 the chips 10.

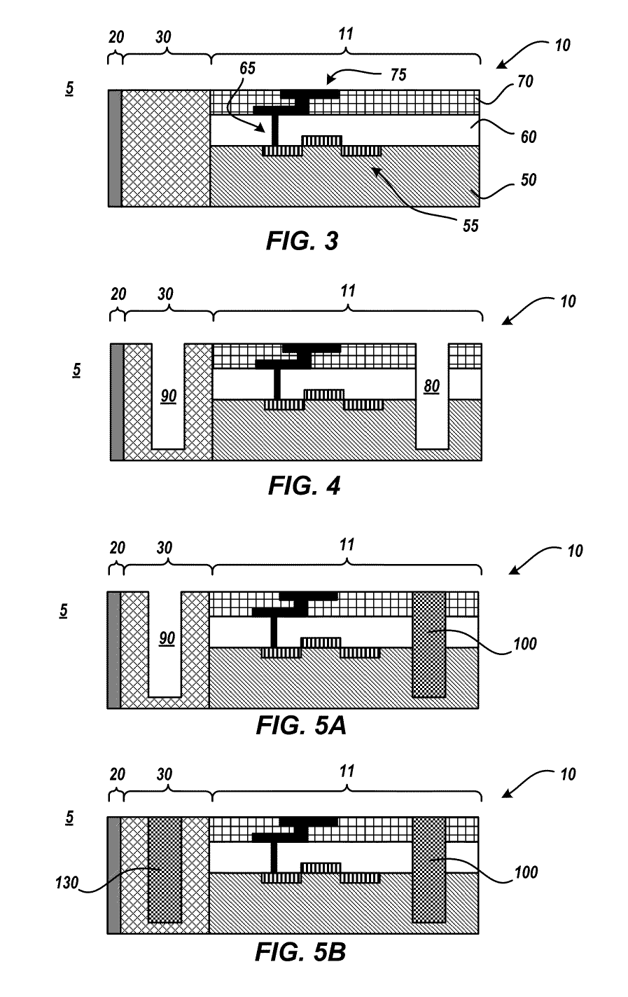

FIG. 3 depicts a cross section view of a semiconductor structure at intermediate stages of semiconductor device fabrication, in accordance with various embodiments of the present invention. For example, at this stage of wafer 5 fabrication, the inner active regions 11 of chips 10 may include a semiconductor substrate 50, a front end of the line (FEOL) layer 60 upon the substrate 50, and BEOL wiring layer 70 upon the FEOL layer 60. In the various embodiments, the semiconductor structure shown in FIG. 3 may be an initial structure that which embodiments of the invention may be realized.

The semiconductor substrate 50 may include, but is not limited to: any semiconducting material such conventional Si-containing materials, Germanium-containing materials, GaAs, InAs and other like semiconductors. Si-containing materials include, but are not limited to: Si, bulk Si, single crystal Si, polycrystalline Si, SiGe, amorphous Si, silicon-on-insulator substrates (SOI), SiGe-on-insulator (SGOI), annealed poly Si, and poly Si line structures. In various embodiments, substrate 50 may be, for example, a layered substrate (e.g. silicon on insulator) or a bulk substrate.

In various embodiments, devices 55 may be formed upon or within the substrate 50. Devices 55 and the process of device 55 fabrication are well known in the art. Devices 55 may be for example, a diode, field effect transistor (FET), metal oxide FET (MOSFET), logic gate, or any suitable combination thereof. Devices 55 also may be components that form a function device such as a gate, fin, source, drain, channel, etc. For clarity, though one device 55 is shown, there are typically numerous devices 55 included within inner active regions 11 of each chip 10. In certain embodiments, devices 55 may be formed within substrate 50. For example, a source and drain may be formed within substrate 50. To electrically isolate various devices 55, chips 10 may include isolation regions (not shown) formed upon and/or within substrate 10 (e.g. an isolation region may electrically isolate an n-FET device 55 from a p-FET device 55, etc.).

The FEOL layer 60 is the layer of chip 10 that generally includes individual devices 55 (e.g. transistors, capacitors, resistors, etc.) patterned in the substrate 50. For example, FinFETs may be implemented in FEOL layer 60 with gate first or gate last FinFET fabrication process techniques. The FEOL layer 60 may include devices 55, one or more dielectric layers, contact 65 to electrically connect device 55 to wiring 75. The BEOL layer 70 is the layer of chip 10 including wiring 75 formed by known wiring 75 fabrication techniques. The BEOL layer 70 may further include one or more dielectric layers and bond sites for chip-to-package connections, etc.

FIG. 4 depicts a cross section view of a semiconductor structure at intermediate stages of semiconductor device fabrication, in accordance with various embodiments of the present invention. For example, at this stage of wafer 5 fabrication, a through-silicon trench 80 is formed in active region 11 and a through-silicon trench 90 is formed within crack stop region 30.

In certain chips 10, a through silicon via (TSV) may be utilized. A TSV is a vertical electrical connection via (Vertical Interconnect Access) passing completely through a silicon wafer or die. TSVs may be used, for example, to allow wafer-to-wafer interconnect schemes such as those compatible with three dimensional wafer-level packaging.

Through-silicon trench 80 and through-silicon trench 90 may be formed, for example, utilizing photolithography and a wet etch, dry etch, or combination. More specifically, a pattern may be produced by applying a masking layer such as a photoresist or photoresist with an underlying hardmask, to the surface to be etched; exposing the photoresist to a pattern of radiation; and then developing the pattern into the photoresist utilizing a resist developer. Once the patterning of the photoresist is completed, the sections covered by the photoresist are protected while the exposed regions are removed using a selective etching process that removes the unprotected regions. In certain embodiments, multiple etches may be employed. For example, a first mask may be used to open the layer(s) over the substrate 50 and open an upper portion of the substrate 50 and a second mask to open a lower portion of the substrate 50.

In various embodiments, through-silicon trench 80 and through-silicon trench 90 may be simultaneously formed. For example, one or more similar etch processes, one or more similar etch masks, one or more similar photoresits, etc. may be employed to form both through-silicon trench 80 and through-silicon trench 90 in a similar trench formation stage. In other embodiments, through-silicon trench 90 may be formed in a stand alone through-silicon trench 90 formation stage. For example, subsequent to the completion of active region 11 formation, through-silicon trench 90 may be formed.

In various embodiments, through-silicon trench 80 and through-silicon trench 90 may be formed to have a similar depth D1. Likewise, the width W1 of through-silicon trench 80 and the width W2 of through-silicon trench 90 may be similar. However, in various embodiments of the invention, W2 may be larger or smaller than W1.

FIG. 5A and FIG. 5B depicts a cross section view of a semiconductor structure at intermediate stages of semiconductor device fabrication, in accordance with various embodiments of the present invention. At this stage of at this stage of wafer 5 fabrication, TSV 100 and/or crack stop via (CSV) 130 are formed.

TSV 100 may be a pillar, stud, etc. and may be fabricated by forming an electrically insulating film 105 (e.g. shown in FIG. 7) on an internal surface of the through-silicon trench 80 and filling the remaining internal space of the through-silicon trench 80 with a conductive material.

CSV 130 may be similar to TSV 100 in that it vertically passies completely through a silicon wafer or die and may be formed in similar fabrication stages. For example, CSV 130 passes through the entire crack stop region 30. However, CSV 130 may differ from TSV 100 in that it need not make electrical connection from above or below. CSV 130 may be a pillar, stud, elongated pillar, straight wall, zigzag wall, mesh, etc. fabricated by forming an electrically insulating film on an internal surface of the through-silicon trench 90 and filling the remaining internal space of the through-silicon trench 90 with a conductive material. In other embodiments, CSV 130 may also be fabricated without forming the electrically insulating film 105 on the internal surface of the through-silicon trench 90 but by directly filling the through-silicon trench 90 with a conductive material. In other words, in certain embodiments, CSV 130 need not be electrically isolated from surrounding crack stop region 30 material.

In some embodiments, and as shown in FIG. 5A, through-silicon trench 90 may be masked during TSV 100 and may remain unfilled. For clarity, the remaining FIGS. depicts the embodiment where through-silicon trench 90 is filled forming CSV 130 though it should be known that further references to CSV 130 may be substitutionally referring to through-silicon trench 90. For example, the references to CSV 130 within FIG. 8-FIG. 11 may be substituted with references to through-silicon trench 90.

In various embodiments, TSV 100 and CSV 130 may be simultaneously formed. For example, one or more similar filling processes, similar fill material, etc. may be employed to form both TSV 100 and CSV 130 in a similar TSV formation stage. In other embodiments, CSV 130 may be formed in a stand alone TSV formation stage. For example, subsequent to the completion of active region 11 formation, CSV 130 may be formed.

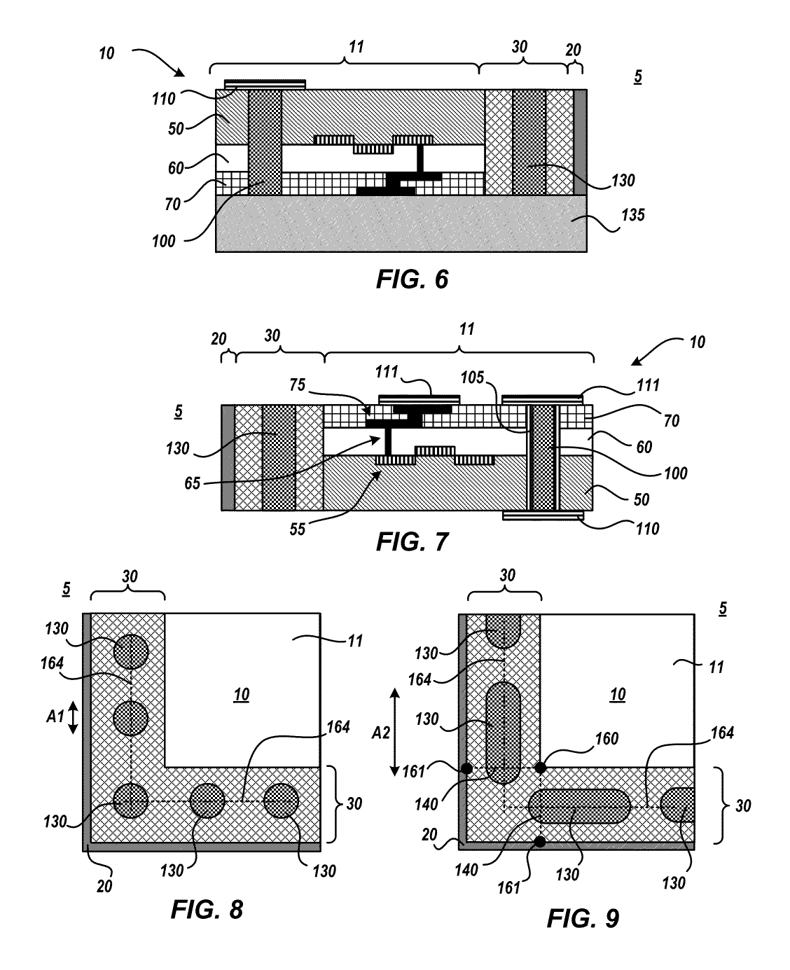

FIG. 6 depicts a cross section view of a semiconductor structure at intermediate stages of semiconductor device fabrication, in accordance with various embodiments of the present invention. At this stage of at this stage of wafer 5 fabrication, a handle 135 attached to the front side of wafer 5, the backside of wafer 5 is planarized and a backside contact 111 is formed.

A handle 135 may be attached to wafer 5 and a grinding may be performed on the backside substrate 50, until TSV 100 and/or CSV 130 are exposed. In this manner TSV 100 passes completely through chip 10 (e.g. TSV 100 passes through substrate 50, BEOL wiring layer 70, FEOL layer 60).

Backside contact 111 may be an electrically conductive pad electrically coupled to TSV 100 and may be fabricated by forming a pad opening in a deposited dielectric layer, forming a seed layer, performing an electrochemical plating (ECP) to fill the opening with a metallic material, and then performing a CMP to remove excess metallic material. Additional metal layers and bumps (not shown) may also be formed on the backside contact 111, and electrically coupled to TSV 100.

FIG. 7 depicts a cross section view of a semiconductor structure at intermediate stages of semiconductor device fabrication, in accordance with various embodiments of the present invention. At this stage of at this stage of wafer 5 fabrication, handle 135 is removed and one or more front side contacts 110 may be formed.

A front side contact 110 may be an electrically conductive pad electrically coupled to TSV 100 or device 55 (via wiring 75 and contact 65) and may be fabricated by forming one or more pad openings in a deposited dielectric layer, forming a seed layer, performing an ECP to fill the opening with a metallic material, and then performing a CMP to remove excess metallic material. Additional metal layers and bumps (not shown) may also be formed on the front side contact 110 and electrically coupled to TSV 100 or device 55.

As shown in FIG. 7, TSV 100 and CSV 130 pass completely through chip 10. For example, TSV 100 passes through substrate 50, BEOL wiring layer 70, FEOL layer 60 whereas CSV 130 passes through the entire crack stop region 30. In certain embodiments, CSV 130 is not electrically coupled to a front side contact 110 nor backside contact 111.

Though C/D 40 generally propagate through the BEOL dielectrics which are generally brittle materials such as silicon oxide, it is beneficial that CSV 130 passes through the entire crack stop region 30 to stop C/D 40 propagation that may occur under the BEOL layer 70 (e.g. though the substrate 50).

FIG. 8 and FIG. 9 depict a top view of a semiconductor structure at intermediate stages of semiconductor device fabrication, in accordance with various embodiments, of the present invention. In the present embodiment, chip 10 includes a crack stop region 30 comprising a plurality of serially arranged TSVs 130. The serially arranged TSVs 130 generally align along a similar plane 164 along the perimeter of chip 10 within crack stop region 30.

In certain embodiments, as exemplarily shown n FIG. 9, one or more TSVs 130 may be arranged to intersect a plane 140 formed between a corner 160 of a chip and a nearest edge of crack stop region 30. The placement of one or more TSVs 130 to intersect plane 140 aids in the prevention of propagation of C/D 40 at corner 160 of the chip 10. The corner 160 of the chip 10 may be more vulnerable to C/D 40 because the corner 160 may be more exposed to separation forces than the sides of chip 10. For example, the corner 160 may be exposed to separation forces caused by dicing not only from one direction but from two orthogonal directions.

In various embodiments, the shape of an upper surface of CSV 130 may be generally circular like, slot like, elliptical like, square like, rectangular like, continuous straight wall, continuous zigzag wall, meshed, etc. One or more CSV 130 may taper as it passes through the crack stop region 30. More particularly, a CSV 130 may have a width A1 on a first side of chip 10 and a width A2 on the opposite side of chip 10. For example, a TSV may have a larger perimeter dimensional value A2 generally nearest BEOL layer 70 and a smaller dimensional perimeter value A1 nearest substrate 50. CSV 130 having the larger perimeter dimensional value A2 generally nearest BEOL layer 70 may aid in the prevention of limiting C/D 40 propagation into the BEOL layer 70 while the smaller dimensional perimeter value A1 nearest substrate 50 may aid in the prevention of limiting C/D 40 propagation into substrate 50.

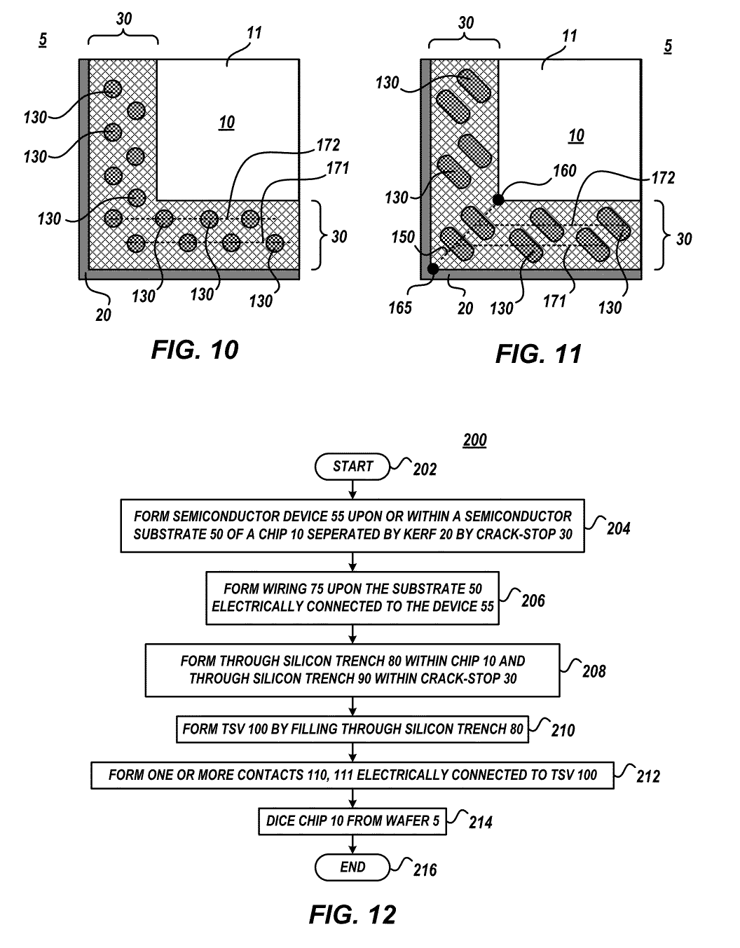

FIG. 10 and FIG. 11 depict a top view of a semiconductor structure at intermediate stages of semiconductor device fabrication, in accordance with various embodiments, of the present invention. In the present embodiment, chip 10 includes a crack stop region 30 comprising a plurality of TSVs 130 staggeredly arranged along differing planes 170, 172 along the perimeter of chip 10 within crack stop region 30.

In certain embodiments, as exemplarily shown n FIG. 11, one or more TSVs 130 may be arranged to intersect a plane 150 formed between corner 160 of a chip and a nearest corner 165 of crack stop region 30. The placement of one or more TSVs 130 to intersect plane 150 aids in the prevention of propagation of C/D 40 at corner 160 of the chip 10.

FIG. 12 depicts an exemplary semiconductor device fabrication process flow method 200, in accordance with various embodiments of the present invention. Method 200 begins at block 202 by forming one or more semiconductor device(s) 55 upon or within a semiconductor substrate 50 within an active region 11 of chip 10 (block 204). The chip 10 may be included within a wafer 5 separated from surrounding chips 10 by kerf 20. The chip 10 may also include a crack stop region adjacent to and separating the active region 11 from the kerf 20.

Method 200 may continue by forming wiring 75 upon substrate 50 electrically coupled to devices 55 (block 206). Method 200 may continue by forming trough silicon trench 80 within the active region 11 of chip 10 and through silicon trench 90 within crack stop region 30 (block 208). In some embodiments, trough silicon trench 80 and through silicon trench 90 may be formed simultaneously (i.e. during similar trench formation processes, etc.). In other embodiments, through silicon trench 90 may be formed in distinct trench formation processes, e.g. subsequent to fabricating active region 11 of chip 10.

Method 200 may continue by forming TSV 100 by filling trough silicon trench 80 with electrically conductive material (block 210). In certain embodiments, an electrically insulating layer 105 is formed adjacent to the walls of trough silicon trench 80 prior to filling the trough silicon trench 80 with electrically conductive material.

Method 200 may continue by forming one or more contacts 110, 111 on the front side or backside of chip 10, respectively, electrically coupled to TSV 100 (block 212). Method 200 may continue with dicing or removing chip 10 from wafer 5 by sawing through kerf 20 (block 214). In various embodiments, of the present invention, the through silicon trench 90 passes through the entire crack stop region 30 to stop C/D 40 propagation that may occur under the BEOL layer 70 (e.g. though the substrate 50) during the dicing or removing chip 10 from wafer 5. Method 200 ends at block 216.

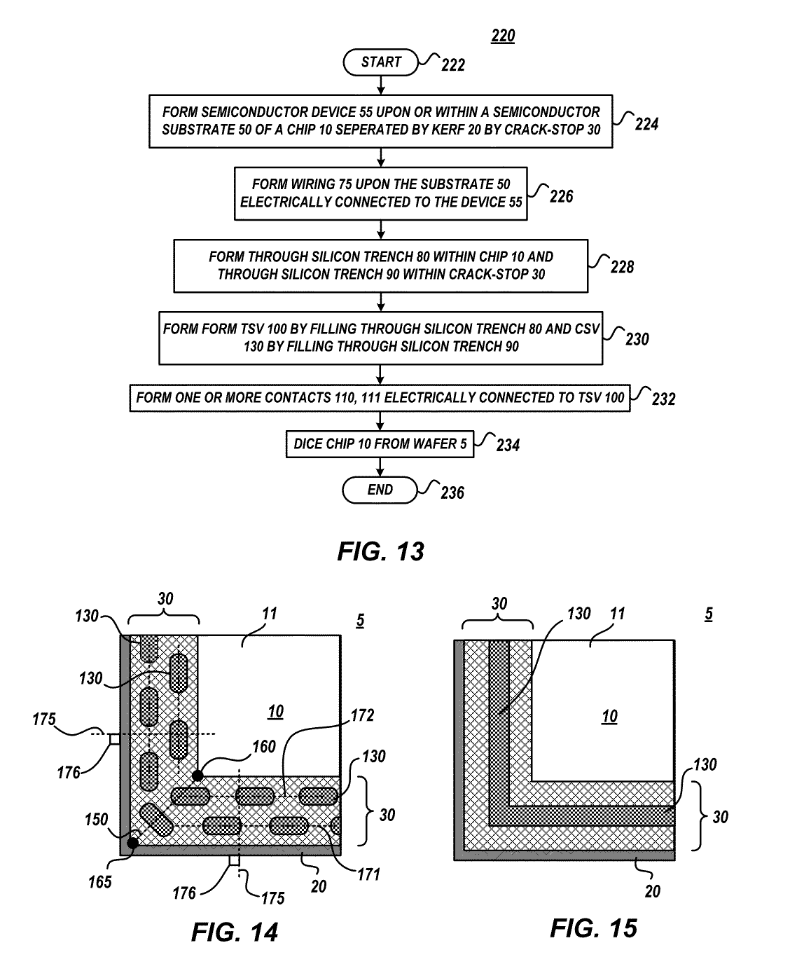

FIG. 13 depicts an exemplary semiconductor device fabrication process flow method 220, in accordance with various embodiments of the present invention. Method 220 begins at block 222 by forming one or more semiconductor device(s) 55 upon or within a semiconductor substrate 50 within an active region 11 of chip 10 (block 224). The chip 10 may be included within a wafer 5 separated from surrounding chips 10 by kerf 20. The chip 10 may also include a crack stop region adjacent to and separating the active region 11 from the kerf 20.

Method 220 may continue by forming wiring 75 upon substrate 50 electrically coupled to devices 55 (block 226). Method 220 may continue by forming trough silicon trench 80 within the active region 11 of chip 10 and through silicon trench 90 within crack stop region 30 (block 228). In some embodiments, trough silicon trench 80 and through silicon trench 90 may be formed simultaneously (i.e. during similar trench formation processes, etc.). In other embodiments, through silicon trench 90 may be formed in distinct trench formation processes, e.g. subsequent to fabricating active region 11 of chip 10.

Method 220 may continue by forming TSV 100 by filling trough silicon trench 80 and forming CSV 130 by filling through silicon trench 90 with electrically conductive material (block 230). In certain embodiments, an electrically insulating layer 105 is formed adjacent to the walls of trough silicon trench 80 prior to filling the trough silicon trench 80 through silicon trench 90 with electrically conductive material.

Likewise, CSV 130 may also be fabricated by forming an electrically insulating film 105 on an internal surface of the through-silicon trench 90 and filling the remaining internal space of the through-silicon trench 90 with a conductive material. In other embodiments, CSV 130 may be fabricated without forming the electrically insulating film 105 on the internal surface of the through-silicon trench 90 but by directly filling the through-silicon trench 90 with a conductive material. In other embodiments, CSV 130 may also be fabricated by forming an electrically insulating film 105 on an internal surface of the through-silicon trench 90 and filling the remaining internal space of the through-silicon trench 90 with one or more nonconductive materials. In other embodiments, CSV 130 may be fabricated without forming the electrically insulating film 105 on the internal surface of the through-silicon trench 90 but by directly filling the through-silicon trench 90 with nonconductive material. In some embodiments, TSV 100 and CSV 130 may be formed simultaneously (i.e. during similar trench formation processes, etc.). In other embodiments, CSV 130 may be formed in distinct trench formation processes, e.g. subsequent to fabricating active region 11 of chip 10.

Method 220 may continue by forming one or more contacts 110, 111 on the front side or backside of chip 10, respectively, electrically coupled to TSV 100 (block 232). In other words, in certain embodiments, CSV 130 is not electrically coupled to contacts 110, 111, etc. Method 220 may continue with dicing or removing chip 10 from wafer 5 by sawing through kerf 20 (block 214). In various embodiments, of the present invention, CSV 130 passes through the entire crack stop region 30 to stop C/D 40 propagation that may occur under the BEOL layer 70 (e.g. though the substrate 50) during the dicing or removing chip 10 from wafer 5. Method 220 ends at block 236.

FIG. 14 depicts a top view of a semiconductor structure at intermediate stages of semiconductor device fabrication, in accordance with various embodiments of the present invention. In the present embodiment, chip 10 includes a crack stop region 30 comprising a plurality of TSVs 130 staggeredly arranged along differing planes 170, 172 along the perimeter of chip 10 within crack stop region 30.

In certain embodiments, as exemplarily shown n FIG. 14, one or more TSVs 130 may be arranged to intersect a plane 150 formed between corner 160 of a chip and a nearest corner 165 of crack stop region 30. The placement of one or more TSVs 130 to intersect plane 150 aids in the prevention of propagation of C/D 40 at corner 160 of the chip 10. In certain embodiments, TSVs 130 may be arranged to intersect any perpendicular plane 175 generally orthogonal 176 to chip 10.

FIG. 15 depicts a top view of a semiconductor structure at intermediate stages of semiconductor device fabrication, in accordance with various embodiments of the present invention. In the present embodiment, chip 10 includes a crack stop region 30 comprising a continuous wall TSV 130 arranged along the perimeter of chip 10 within crack stop region 30. Continuous wall TSV 130 is an uninterrupted wall that transitions from one side of the crack stop region 30 to another side of the crack stop region 30.

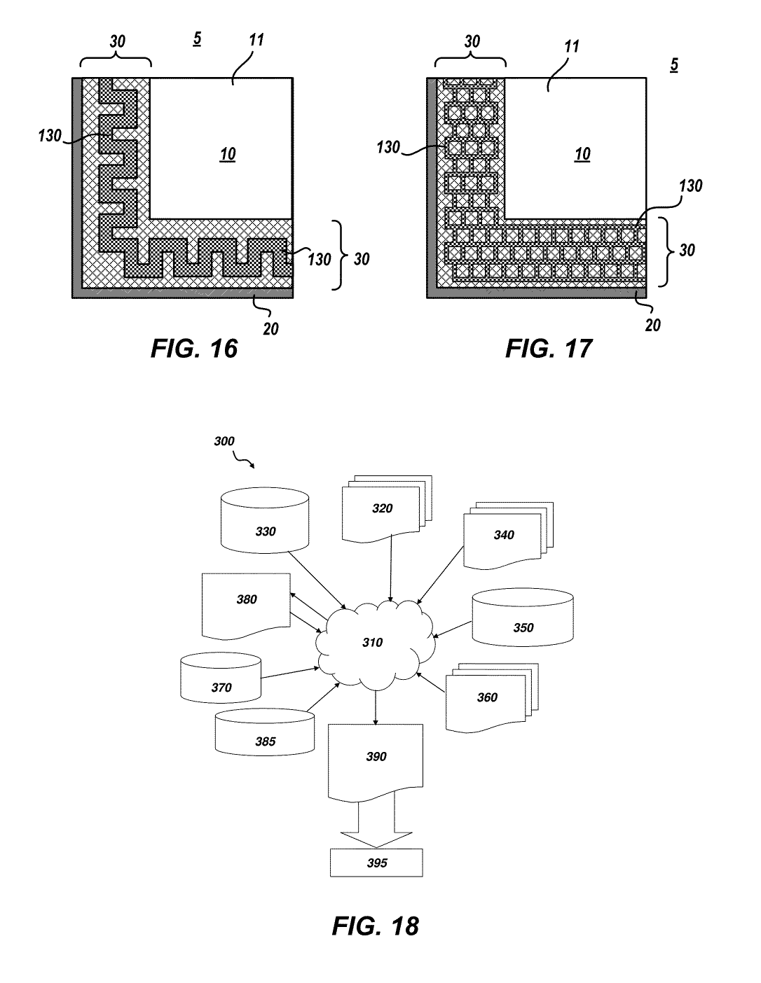

FIG. 16 depicts a top view of a semiconductor structure at intermediate stages of semiconductor device fabrication, in accordance with various embodiments of the present invention. In the present embodiment, chip 10 includes a crack stop region 30 comprising a continuous zigzag wall TSV 130 arranged along the perimeter of chip 10 within crack stop region 30. Continuous zigzag wall TSV 130 is an uninterrupted serpentine wall that transitions from one side of the crack stop region 30 to another side of the crack stop region 30.

FIG. 17 depicts a top view of a semiconductor structure at intermediate stages of semiconductor device fabrication, in accordance with various embodiments of the present invention. In the present embodiment, chip 10 includes a crack stop region 30 comprising a continuous mesh TSV 130 arranged along the perimeter of chip 10 within crack stop region 30. The mesh TSV 130 may be a square like mesh, a rectangular like mesh, a circular like mesh, a hexagonal like mesh, etc. Continuous mesh TSV 130 is an uninterrupted mesh that transitions from one side of the crack stop region 30 to another side of the crack stop region 30.

Referring now to FIG. 18, a block diagram of an exemplary design flow 300 used for example, in semiconductor integrated circuit (IC) logic design, simulation, test, layout, and/or manufacture is shown. Design flow 300 includes processes, machines and/or mechanisms for processing design structures or devices to generate logically or otherwise functionally equivalent representations of the structures and/or devices described above and shown in FIGS. 3-11, 14-17, etc.

The design structures processed and/or generated by design flow 300 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 300 may vary depending on the type of representation being designed. For example, a design flow 300 for building an application specific IC (ASIC) may differ from a design flow 300 for designing a standard component or from a design flow 300 for instantiating the design into a programmable array, for example a programmable gate array (PGA) or a field programmable gate array (FPGA) offered by Altera® Inc. or Xilinx® Inc.

FIG. 18 illustrates multiple such design structures including an input design structure 320 that is preferably processed by a design process 310. Design structure 320 may be a logical simulation design structure generated and processed by design process 310 to produce a logically equivalent functional representation of a hardware device. Design structure 320 may also or alternatively comprise data and/or program instructions that when processed by design process 310, generate a functional representation of the physical structure of a hardware device. Whether representing functional and/or structural design features, design structure 320 may be generated using electronic computer-aided design (ECAD) such as implemented by a core developer/designer.

When encoded on a machine-readable data transmission, gate array, or storage medium, design structure 320 may be accessed and processed by one or more hardware and/or software modules within design process 310 to simulate or otherwise functionally represent an electronic component, circuit, electronic or logic module, apparatus, device, structure, or system such as those shown in FIGS. 3-11, 14-17, etc. As such, design structure 320 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 310 preferably employs and incorporates hardware and/or software modules for synthesizing, translating, or otherwise processing a design/simulation functional equivalent of the components, circuits, devices, or structures shown FIGS. 3-11, 14-17, etc. to generate a Netlist 380 which may contain design structures such as design structure 320. Netlist 380 may comprise, for example, compiled or otherwise processed data structures representing a list of wires, discrete components, logic gates, control circuits, I/O devices, models, etc. that describes the connections to other elements and circuits in an integrated circuit design. Netlist 380 may be synthesized using an iterative process in which netlist 380 is resynthesized one or more times depending on design specifications and parameters for the device. As with other design structure types described herein, netlist 380 may be recorded on a machine-readable data storage medium or programmed into a programmable gate array. The storage medium may be a non-volatile storage medium such as a magnetic or optical disk drive, a programmable gate array, a compact flash, or other flash memory. Additionally, or in the alternative, the storage medium may be a system or cache memory, buffer space, or electrically or optically conductive devices in which data packets may be intermediately stored.

Design process 310 may include hardware and software modules for processing a variety of input data structure types including Netlist 380. Such data structure types may reside, for example, within library elements 330 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 340, characterization data 350, verification data 360, design rules 370, and test data files 385 which may include input test patterns, output test results, and other testing information. Design process 310 may further include, for example, standard mechanical design processes such as stress analysis, thermal analysis, mechanical event simulation, process simulation for operations such as casting, molding, and die press forming, etc.

One of ordinary skill in the art of mechanical design can appreciate the extent of possible mechanical design tools and applications used in design process 310 without deviating from the scope and spirit of the invention claimed herein. Design process 310 may also include modules for performing standard circuit design processes such as timing analysis, verification, design rule checking, place and route operations, etc.

Design process 310 employs and incorporates logic and physical design tools such as HDL compilers and simulation model build tools to process design structure 320 together with some or all of the depicted supporting data structures along with any additional mechanical design or data (if applicable), to generate a second design structure 390. Design structure 390 resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures).

Similar to design structure 320, design structure 390 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 3-11, 14-17, etc. In one embodiment, design structure 390 may comprise a compiled, executable HDL simulation model that functionally simulates the devices shown in FIGS. 3-11, 14-17, etc.

Design structure 390 may also employ a data format used for the exchange of layout data of integrated circuits and/or symbolic data format (e.g. information stored in a GDSII (GDS2), GL1, OASIS, map files, or any other suitable format for storing such design data structures). Design structure 390 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 3-11, 14-17, etc. Design structure 390 may then proceed to a stage 395 where, for example, design structure 390: proceeds to tape-out, is released to manufacturing, is released to a mask house, is sent to another design house, is sent back to the customer, etc.

The accompanying figures and this description depicted and described embodiments of the present invention, and features and components thereof. Those skilled in the art will appreciate that any particular nomenclature used in this description was merely for convenience, and thus the invention should not be limited by the specific process identified and/or implied by such nomenclature. Therefore, it is desired that the embodiments described herein be considered in all respects as illustrative, not restrictive, and that reference be made to the appended claims for determining the scope of the invention.

The exemplary methods and techniques described herein may be used in the fabrication of integrated circuit chips. The resulting integrated circuit chips can be distributed by the fabricator in raw wafer form (i.e., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). The chip is then integrated with other chips, discrete circuit elements and/or other signal processing devices as part of either (a) an intermediate product, such as a motherboard, or (b) an end product. The end product can be any product that includes integrated circuit chips, ranging from toys and other low-end applications to advanced computer products having numerous components, such as a display, a keyboard or other input device and/or a central processor, as non-limiting examples.

References herein to terms such as “vertical”, “horizontal”, etc. are made by way of example, and not by way of limitation, to establish a frame of reference. The term “horizontal” as used herein is defined as a plane parallel to the conventional plane or surface of the substrate, regardless of the actual spatial orientation of the semiconductor substrate. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

1. A semiconductor device comprising:
an active inner region comprising: a semiconductor substrate; an integrated circuit (IC) device layer formed upon the semiconductor substrate, the IC device layer comprising an integrated circuit devices of the semiconductor device; a wiring layer formed upon the IC device layer, the wiring layer comprising wiring making electrical contact with the integrated circuit devices, and;
a crack stop region at the periphery of the active inner region that limits the propagation of cracks and delamination into the active inner region, the crack stop region comprising semiconductor material surrounding a serpentine-shaped crack stop via (CSV) extending through the crack stop region and is void of an integrated circuit device.

2. The semiconductor device of claim 1, wherein the active inner region further comprises a lower surface of the semiconductor substrate and an upper surface of the wiring layer, wherein the crack stop region further comprises an lower surface that is coplanar with the lower surface of the active inner region and an upper surface that is coplanar with the upper surface of the active inner region, and wherein the serpentine-shaped CSV comprises an lower surface coplanar with the lower surface of the crack stop region and a upper surface coplanar with the upper surface of the crack stop region.

3. The semiconductor device of claim 1, further comprising,
a through-silicon-via (TSV) extending through the semiconductor substrate, the IC device layer, and the wiring layer.

4. The semiconductor device of claim 3, further comprising,
a first contact pad in electrical contact with an lower surface of the TSV and a second contact pad in electrical contact with an upper surface of the TSV.

5. The semiconductor device of claim 3, wherein the active inner region further comprises:
insulating film electrically isolating the TSV from the semiconductor substrate, the IC device layer, and the wiring layer.

6. The semiconductor device of claim 4, wherein the crack stop region further comprises:
insulating film upon sidewalls of the serpentine-shaped CSV.

7.-9. (canceled)

10. The semiconductor device of claim 1, wherein the serpentine-shaped CSV includes a continuous serpentine-shaped wall that is uninterrupted in transitioning from a first crack stop region adjacent to a first side of the active inner region to a second crack stop region adjacent to a second side to of the active inner region.

11. A wafer comprising:
a plurality of chips each comprising;
an active inner region that comprises: a semiconductor substrate; an integrated circuit (IC) device layer formed upon the semiconductor substrate, the IC device layer comprising an integrated circuit device; a wiring layer formed upon the IC device layer, the wiring layer comprising wiring making electrical contact with the integrated circuit device, and;
a crack stop region at the periphery of the active inner region that limits the propagation of cracks and delamination into the active inner region, the crack stop region comprising semiconductor material surrounding a serpentine-shaped crack stop via (CSV) extending through the crack stop region and is void of an integrated circuit device, and;
a kerf at the periphery of the plurality of chips.

12. The wafer of claim 11, wherein the active inner region further comprises a lower surface of the semiconductor substrate and an upper surface of the wiring layer, wherein the crack stop region further comprises an lower surface that is coplanar with the lower surface of the active inner region and an upper surface that is coplanar with the upper surface of the active inner region, and wherein the serpentine-shaped CSV comprises an lower surface coplanar with the lower surface of the crack stop region and a upper surface coplanar with the upper surface of the crack stop region.

13. The semiconductor device of claim 11, further comprising,
a through-silicon-via (TSV) extending through the semiconductor substrate, the IC device layer, and the wiring layer.

14. The wafer of claim 13, wherein each chip further comprises,
a first contact pad in electrical contact with an lower surface of the TSV and a second contact pad in electrical contact with an upper surface of the TSV.

15. The wafer of claim 13, wherein the active inner region further comprises:
insulating film electrically isolating the TSV from the semiconductor substrate, the IC device layer, and the wiring layer.

16. The wafer of claim 11, wherein the crack stop region further comprises:
insulating film upon sidewalls of the serpentine-shaped CSV.

17.-19. (canceled)

20. The wafer of claim 11, wherein the serpentine-shaped CSV includes a serpentine-shaped continuous wall that is uninterrupted in transitioning from a first crack stop region adjacent to a first side of the active inner region to a second crack stop region adjacent to a second side to of the active inner region.

21. A semiconductor device comprising:
an active inner region comprising: a semiconductor substrate; an integrated circuit (IC) device layer formed upon the semiconductor substrate, the IC device layer comprising a integrated circuit device; a wiring layer formed upon the IC device layer, the wiring layer comprising wiring making electrical contact with the integrated circuit device, and;
a crack stop region at the periphery of the active inner region that limits the propagation of cracks and delamination into the active inner region, the crack stop region comprising semiconductor material surrounding a mesh crack stop via (CSV) extending through the crack stop region and is void of an integrated circuit device.

22. The semiconductor device of claim 21, wherein the active inner region further comprises a lower surface of the semiconductor substrate and an upper surface of the wiring layer, wherein the crack stop region further comprises an lower surface that is coplanar with the lower surface of the active inner region and an upper surface that is coplanar with the upper surface of the active inner region, and wherein the mesh CSV comprises an lower surface coplanar with the lower surface of the crack stop region and a upper surface coplanar with the upper surface of the crack stop region.

23. The semiconductor device of claim 21, further comprising,
a through-silicon-via (TSV) extending through the semiconductor substrate, the IC device layer, and the wiring layer.

24. The semiconductor device of claim 23, further comprising,
a first contact pad in electrical contact with an lower surface of the TSV and a second contact pad in electrical contact with an upper surface of the TSV.

25. The semiconductor device of claim 23, wherein the active inner region further comprises:
insulating film electrically isolating the TSV from the semiconductor substrate, the IC device layer, and the wiring layer.

26. The semiconductor device of claim 23, wherein the mesh CSV includes a continuous mesh that is uninterrupted in transitioning from a first crack stop region adjacent to a first side of the active inner region to a second crack stop region adjacent to a second side to of the active inner region.
